(19) United States
(12) Patent Application Publication
(10) Pub. No.: US 2015/0318295 A1
(43) Pub. Date: Nov. 5, 2015

(54) VERTICAL FLOATING GATE NAND WITH OFFSET DUAL CONTROL GATES

(71) Applicant: SanDisk Technologies, Inc., Plano, TX (US)

(72) Inventors: James Kai, Fremont, CA (US); Vinod Purayath, Santa Clara, CA (US); Donovan Lee, Santa Clara, CA (US); Akira Matsudaira, San Jose, CA (US)

(73) Assignee: SanDisk Technologies, Inc., Plano, TX (US)

(21) Appl. No.: 14/265,733

(22) Filed: Apr. 30, 2014

(51) Int. Cl. H01L 27/115; H01L 21/285; H01L 21/28; H01L 21/02; H01L 29/423; H01L 29/788

(52) U.S. Cl. CPC H01L 27/11556; H01L 29/42328; H01L 29/7883; H01L 21/28273; H01L 21/02164; H01L 21/0217; H01L 21/28568

(57) ABSTRACT

A method of making a monolithic three dimensional NAND string includes providing a stack of alternating insulating layers and control gate films over a major surface of a substrate. Each of the control gate films includes a middle layer located between a first control gate layer and a second control gate layer, the middle layer being a different material from the first and second control gate layers and from the insulating layers. The method also includes forming a front side opening in the stack, and forming a blocking dielectric, at least one charge storage region, a tunnel dielectric and a semiconductor channel in the front side opening in the stack.

### FIELD

The present invention relates generally to the field of semiconductor devices and specifically to three dimensional vertical NAND strings and other three dimensional devices and methods of making thereof.

### BACKGROUND

Three dimensional vertical NAND strings are disclosed in an article by T. Endoh, et. al., titled “Novel Ultra High Density Memory With A Stacked-Surrounding Gate Transistor (S-SGT) Structured Cell”, IEDM Proc. (2001) 33-36. However, this NAND string provides only one bit per cell. Furthermore, the active regions of the NAND string is formed by a relatively difficult and time consuming process involving repeated formation of sidewall spacers and etching of a portion of the substrate, which results in a roughly conical active region shape.

### SUMMARY

An embodiment relates to a method of making a monolithic three dimensional NAND string including providing a stack of alternating insulating layers and control gate films over a major surface of a substrate, each of the control gate films comprising: a middle layer located between a first control gate layer and a second control gate layer, the middle layer comprising a different material from the first and second control gate layers and from the insulating layers, forming a front side opening in the stack and forming a blocking dielectric, at least one charge storage region, a tunnel dielectric and a semiconductor channel in the front side opening in the stack.

Another embodiment relates a monolithic three dimensional NAND string including a stack of alternating insulating layers and control gate films over a major surface of a substrate, each of the control gate films comprising: an insulating middle layer located between a first control gate layer and a second control gate layer. The insulating middle layer includes a different material from the first and second control gate layers and from the insulating layers. The NAND string also includes a semiconductor channel, wherein at least one end of the semiconductor channel extends through the stack substantially perpendicular to the major surface of the substrate, a first charge storage region and a first portion of a blocking dielectric located in a recess between the first and the second control gate layers of a first control gate film in a first device level, wherein the first portion of the blocking dielectric is located between the first charge storage region and the insulating middle layer of the first control gate film and a first electrically conductive connection layer which contacts the first and second control gate layers in the first control gate film. The first electrically conductive connection layer is separated from the first charge storage region by the insulating middle layer of the first control gate film. The NAND string also includes a second charge storage region and a second portion of the blocking dielectric located in a recess between the first and the second control gate layers of a second control gate film in a second device level. The second portion of the blocking dielectric is located between the second charge storage region and the insulating middle layer of the second control gate film. The NAND string also includes a second electrically conductive connection layer which contacts the first and second control gate layers in the second control gate film. The second electrically conductive connection layer is separated from the second charge storage region by the insulating middle layer of the second control gate film. The NAND string also includes a tunnel dielectric located between the semiconductor channel and the first and second charge storage regions.

### BRIEF DESCRIPTION OF THE DRAWINGS

FIGS. 1A and 1B are respectively side cross sectional and top cross sectional views of a conventional NAND string. FIG. 1A is a side cross sectional view of the device along line Y-Y′ in FIG. 1B, while FIG. 1B is a side cross sectional view of the device along line X-X′ in FIG. 1A.

FIGS. 2A and 2B are respectively side cross sectional and top cross sectional views of another conventional NAND string. FIG. 2A is a side cross sectional view of the device along line Y-Y′ in FIG. 2B, while FIG. 2B is a side cross sectional view of the device along line X-X′ in FIG. 2A.

FIG. 3A is a side cross sectional view of a conventional NAND string of an embodiment with a U-shaped channel. FIG. 3B is a side cross sectional view of another conventional NAND string.

FIGS. 4A-4H are side cross sectional schematic illustrations of a method of making a NAND string according to an embodiment.

FIGS. 5A-5D are side cross sectional schematic illustrations of a method of making a NAND string according to another embodiment.

FIGS. 5E-5F are side cross sectional schematic illustrations of alternative steps for the steps illustrated in FIGS. 5C and 5D in the method illustrated in FIGS. 5A-5D.

FIG. 6 is a side cross sectional schematic view of a NAND string with pillar shaped channel according to an embodiment.

### DETAILED DESCRIPTION

The present inventors have realized that monolithic three dimensional NAND string memory arrays with a reduced word line resistance can be made compared to devices with similar sized memory holes by including two word lines (i.e., control gates) per memory cell. Optionally, the word line resistance can be further decreased by substituting some or all of the semiconductor word line material with a metal or metal alloy, such as tungsten. The architecture of the disclosed NAND string has reduced read/program disturbs and provides better channel boosting due to improved control gate current. In an embodiment discussed in more detail below, the memory cells may be reduced in size by off-setting the control gates to the sides of the floating gates. The architecture also allows for increased string current.

A monolithic three dimensional memory array is one in which multiple memory levels are formed above a single substrate, such as a semiconductor wafer, with no intervening substrates. The term “monolithic” means that layers of each level of the array are directly deposited on the layers of each underlying level of the array. In contrast, two dimensional arrays may be formed separately and then packaged together to form a non-monolithic memory device. For example, non-monolithic stacked memories have been constructed by forming memory levels on separate substrates and adhering the memory levels atop each other, as in Leedy, U.S. Pat. No. 5,915,167, titled “Three Dimensional Structure Memory.” The substrates may be thinned or removed from the memory levels before bonding, but as the memory levels are initially formed over separate substrates, such memories are not true monolithic three dimensional memory arrays.

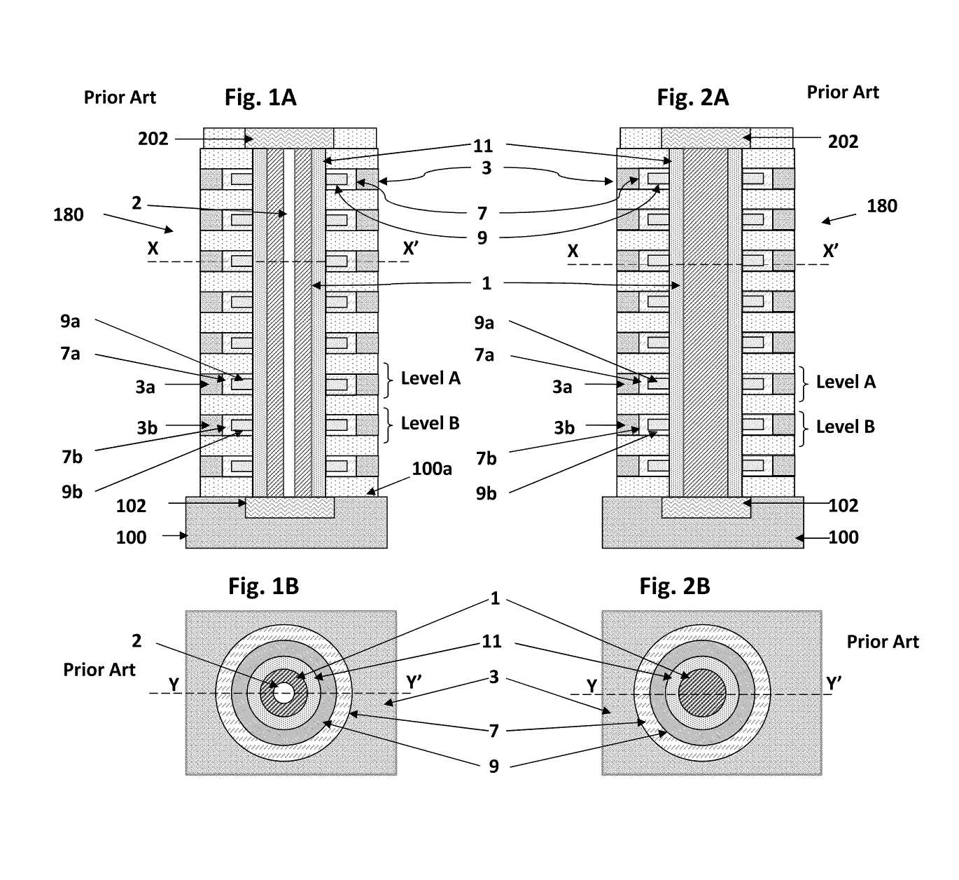

In some embodiments, the monolithic three dimensional NAND string 180 comprises a semiconductor channel 1 having at least one end portion extending substantially perpendicular to a major surface 100a of a substrate 100, as shown in FIGS. 1A, 2A and 3B. “Substantially perpendicular to” (or “substantially parallel to”) means within 0-10°. For example, the semiconductor channel 1 may have a pillar shape and the entire pillar-shaped semiconductor channel extends substantially perpendicularly to the major surface of the substrate 100, as shown in FIGS. 1A, 2A and 3B. In these embodiments, the source/drain electrodes of the device can include a lower electrode 102 provided below the semiconductor channel 1 and an upper electrode 202 formed over the semiconductor channel 1, as shown in FIGS. 1A and 2A.

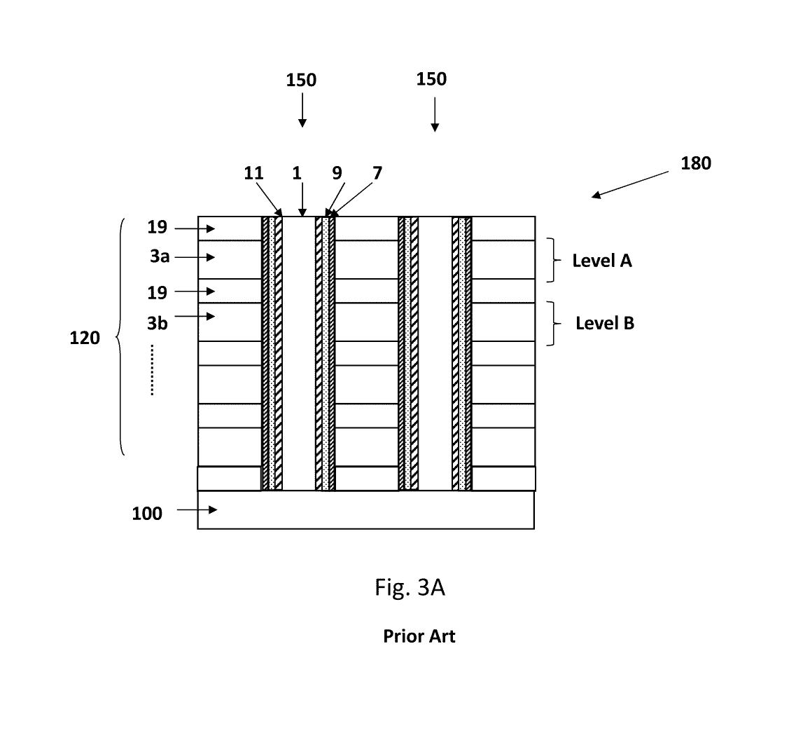

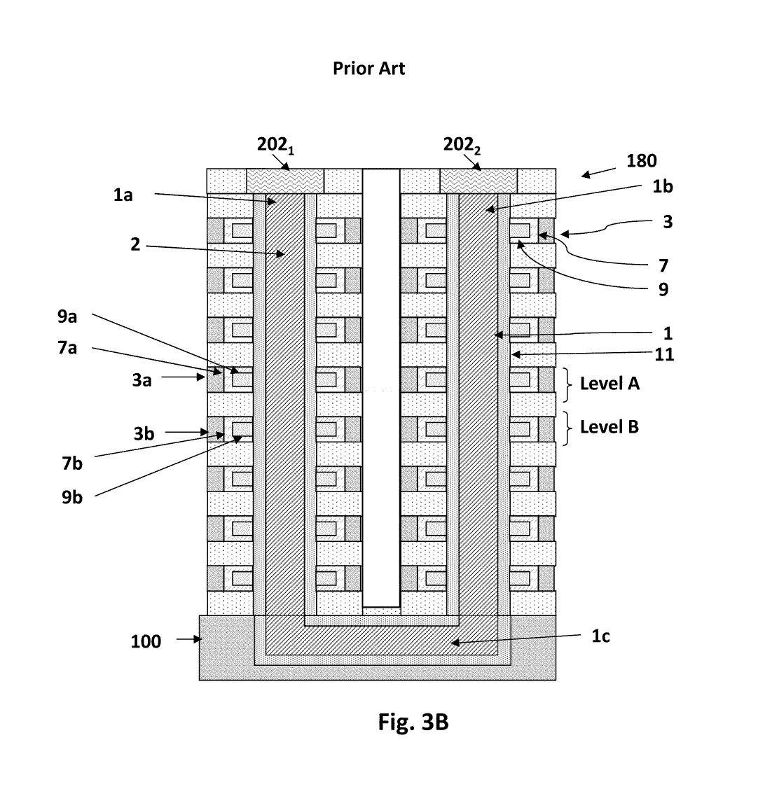

Alternatively, the semiconductor channel 1 may have a U-shaped pipe shape, as shown in FIG. 3A. The two wing portions 1a and 1b of the U-shaped pipe shape semiconductor channel may extend substantially perpendicular to the major surface 100a of the substrate 100, and a connecting portion 1c of the U-shaped pipe shape semiconductor channel 1 connects the two wing portions 1a, 1b extends substantially parallel to the major surface 100a of the substrate 100. In these embodiments, one of the source or drain electrodes 202₁ contacts the first wing portion of the semiconductor channel from above, and another one of a source or drain electrodes 202₂ contacts the second wing portion of the semiconductor channel 1 from above. An optional body contact electrode (not shown) may be disposed in the substrate 100 to provide body contact to the connecting portion of the semiconductor channel 1 from below. The NAND string's select or access transistors are not shown in FIGS. 1-3B for clarity.

In some embodiments, the semiconductor channel 1 may be a filled feature, as shown in FIGS. 2A, 2B, 3A and 3B. In some other embodiments, the semiconductor channel 1 may be hollow, for example a hollow cylinder filled with an insulating fill material 2, as shown in FIGS. 1A-1B. In these embodiments, an insulating fill material 2 may be formed to fill the hollow part surrounded by the semiconductor channel 1. The U-shaped pipe shape semiconductor channel 1 shown in FIG. 3A and/or the channel 1 shown in FIG. 3B may alternatively be a hollow cylinder filled with an insulating fill material 2, shown in FIGS. 1A-1B.

The substrate 100 can be any semiconducting substrate known in the art, such as monocrystalline silicon, IV-IV compounds such as silicon-germanium or silicon-germanium-carbon, III-V compounds, II-VI compounds, epitaxial layers over such substrates, or any other semiconducting or non-semiconducting material, such as silicon oxide, glass, plastic, metal or ceramic substrate. The substrate 100 may include integrated circuits fabricated thereon, such as driver circuits for a memory device.

Any suitable semiconductor materials can be used for semiconductor channel 1, for example silicon, germanium, silicon germanium, or other compound semiconductor materials, such as III-V, II-VI, or conductive or semiconductive oxides, etc. The semiconductor material may be amorphous, polycrystalline or single crystal. The semiconductor channel material may be formed by any suitable deposition methods. For example, in one embodiment, the semiconductor channel material is deposited by low pressure chemical vapor deposition (LPCVD). In some other embodiments, the semiconductor channel material may be a recrystallized polycrystalline semiconductor material formed by recrystallizing an initially deposited amorphous semiconductor material.

The insulating fill material 2 may comprise any electrically insulating material, such as silicon oxide, silicon nitride, silicon oxynitride, or other high-k insulating materials.

The monolithic three dimensional NAND string further comprise a plurality of control gate electrodes 3, as shown in FIGS. 1A-1B, 2A-2B, 3A and 3B. The control gate electrodes 3 may comprise a portion having a strip shape extending substantially parallel to the major surface 100a of the substrate 100. The plurality of control gate electrodes 3 comprise at least a first control gate electrode 3a located in a first device level (e.g., device level A) and a second control gate electrode 3b located in a second device level (e.g., device level B) located over the major surface 100a of the substrate 100 and below the device level A. The control gate material may comprise any one or more suitable conductive or semiconductor control gate material known in the art, such as doped polysilicon, tungsten, tungsten nitride, copper, aluminum, tantalum, titanium, cobalt, titanium nitride or alloys thereof. For example, the control gate material in FIGS. 1A, 2A and 3A may comprise a conductive metal or metal alloy, such as tungsten and/or titanium nitride, while the control gate material in FIG. 3B may comprise doped polysilicon.

A blocking dielectric 7 is located adjacent to the control gate(s) 3 and may surround the control gate 3, as shown in FIGS. 1A, 2A and 3A. Alternatively, a straight blocking dielectric layer 7 may be located only adjacent to an edge (i.e., minor surface) of each control gate 3, as shown in FIG. 3B. The blocking dielectric 7 may comprise a layer having plurality of blocking dielectric segments located in contact with a respective one of the plurality of control gate electrodes 3, for example a first dielectric segment 7a located in device level A and a second dielectric segment 7b located in device level B are in contact with control electrodes 3a and 3b, respectively, as shown in FIG. 3A. Alternatively, the blocking dielectric 7 may be a straight, continuous layer, as shown in FIG. 3B, similar to the device described in U.S. Pat. No. 8,349,681 issued on Jan. 8, 2013 and incorporated herein by reference in its entirety.

The monolithic three dimensional NAND string also comprise a charge storage region 9. The charge storage region 9 may comprise one or more continuous layers which extend the entire length of the memory cell portion of the NAND string, as shown in FIG. 3B. For example, the charge storage region 9 may comprise an insulating charge trapping material, such as a silicon nitride layer.

Alternatively, the charge storage region may comprise a plurality of discrete charge storage regions 9, as shown in FIGS. 1A, 2A and 3A. The plurality of discrete charge storage regions 9 comprise at least a first discrete charge storage region 9a located in the device level A and a second discrete charge storage region 9b located in the device level B, as shown in FIG. 3A. The discrete charge storage regions 9 may comprise a plurality of vertically spaced apart, conductive (e.g., metal such as tungsten, molybdenum, tantalum, titanium, platinum, ruthenium, and alloys thereof, or a metal silicide such as tungsten silicide, molybdenum silicide, tantalum silicide, titanium silicide, nickel silicide, cobalt silicide, or a combination thereof), or semiconductor (e.g., polysilicon) floating gates. Alternatively, the discrete charge storage regions 9 may comprise an insulating charge trapping material, such as silicon nitride segments.

The tunnel dielectric 11 of the monolithic three dimensional NAND string is located between charge storage region 9 and the semiconductor channel 1.

The blocking dielectric 7 and the tunnel dielectric 11 may be independently selected from any one or more same or different electrically insulating materials, such as silicon oxide, silicon nitride, silicon oxynitride, or other insulating materials. The blocking dielectric 7 and/or the tunnel dielectric 11 may include multiple layers of silicon oxide, silicon nitride and/or silicon oxynitride (e.g., ONO layers).

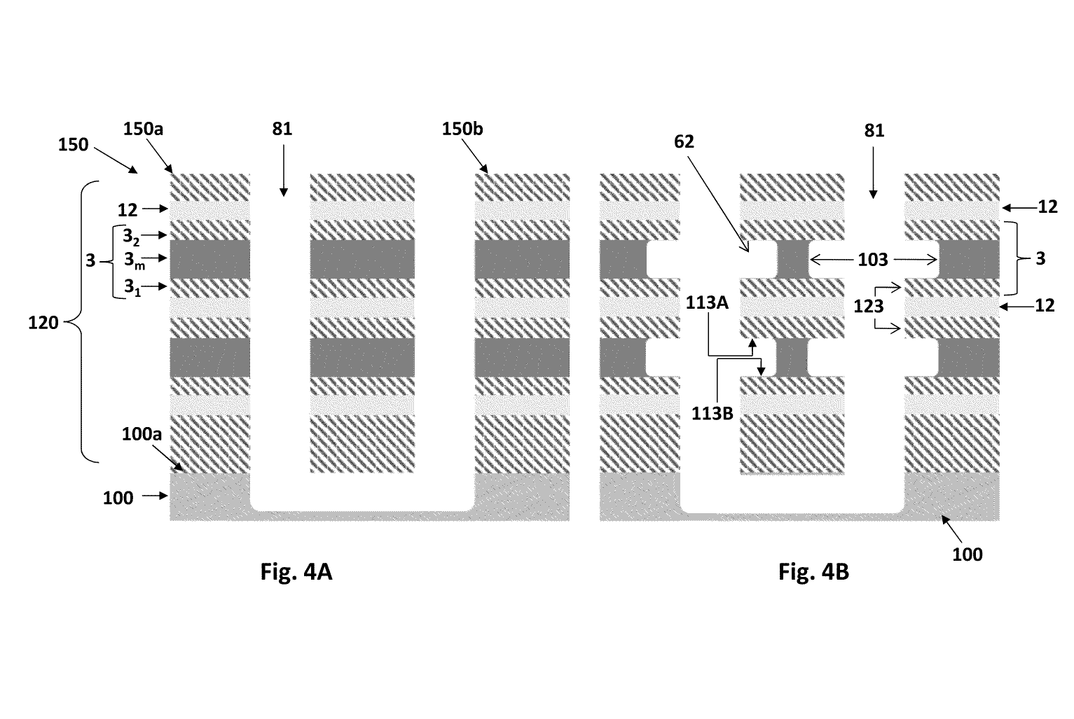

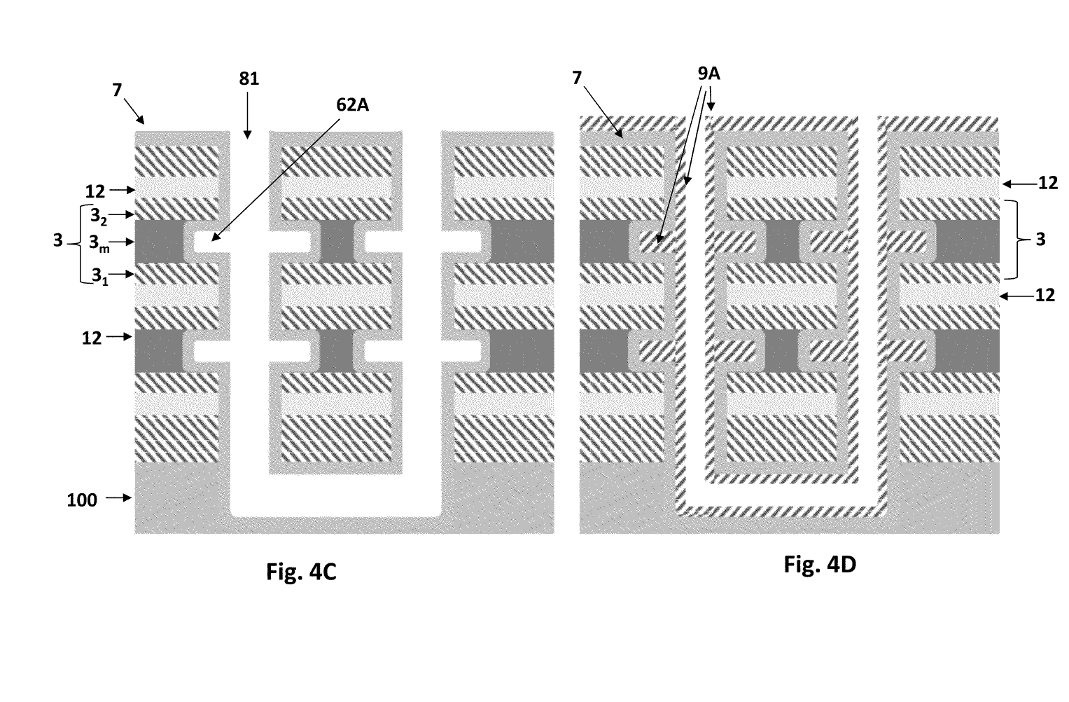

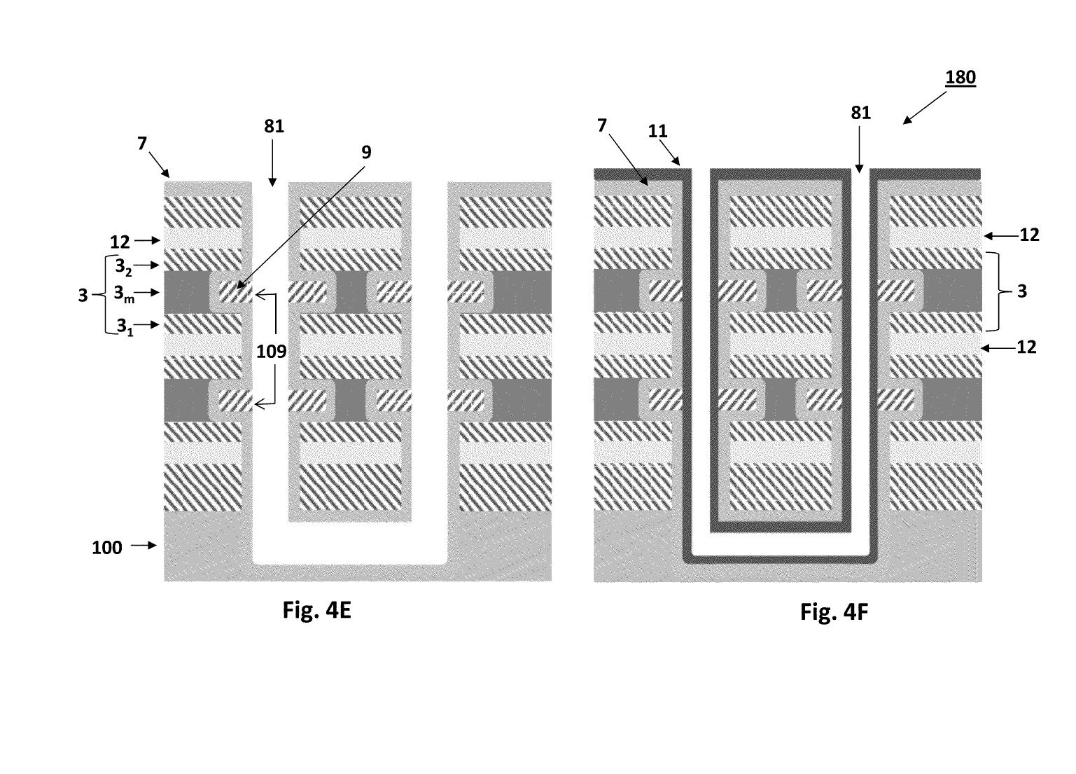

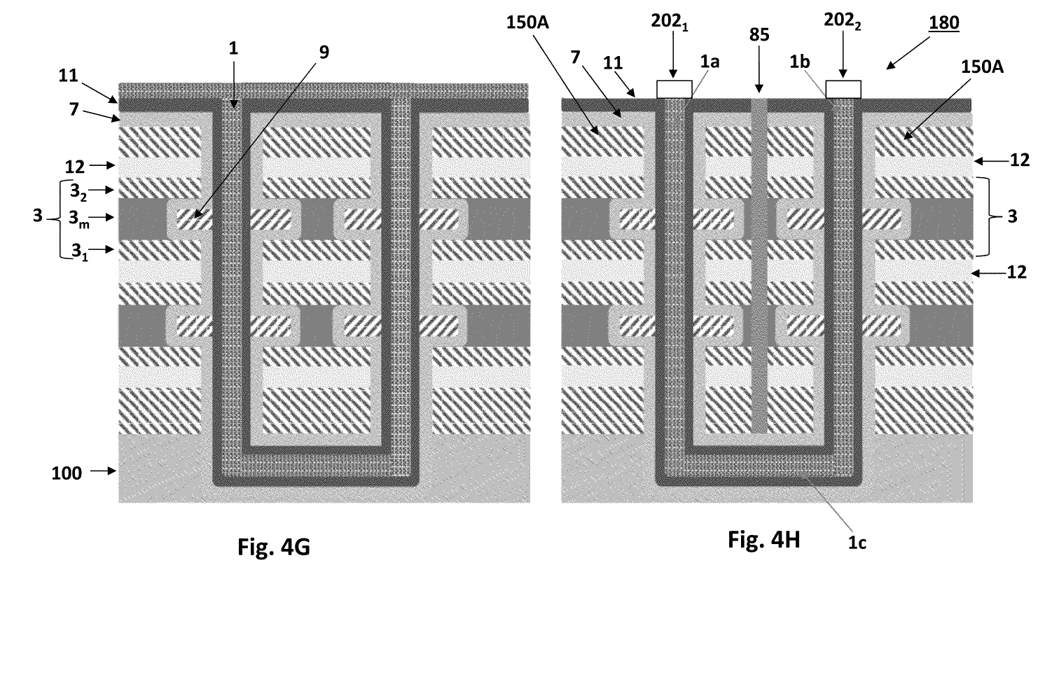

A method of making a NAND string 180 according to an embodiment is illustrated in FIGS. 4A-4H. In this embodiment, a stack 120 of alternating insulating layers 12 and control gate films 3 are provided over a major surface 100a of a substrate 100 as illustrated in FIG. 4A. Each of the control gate films 3 includes a middle layer 3ₘ located between a first control gate layer 3₁ and a second control gate layer 3₂. The middle layer 3ₘ is made preferably of a different material from the first and second control gate layers 3₁, 3₂ and from the insulating layers 12. A select gate layer is located over the stack.

The method includes forming a front side opening 81 (e.g. a memory hole) in the stack 120 as illustrated in FIG. 4A. Also included is a select gate layer 150 which may be patterned to form source/drain select gates 150a, 150b. In the alternative embodiment illustrated in FIG. 7, which is discussed in more detail below, a first source/drain select gate 150a is formed on the bottom of the stack 120 while a second source/drain side select gate 150b is formed on the top of the stack 120.

Next, as illustrated in FIG. 4B, the method includes removing a portion of the middle layer 3ₘ through the front side opening 81 in the stack 120 thereby forming a plurality of front side recesses 62. The middle layer 3ₘ may be removed by a selective wet etch which etches the material of middle layer 3ₘ preferentially to control gate layers 3₁, 3₂. Each of the plurality of recesses 62 is located in each respective control gate film 3 between the first and second control gate layers 3₁, 3₂.

Next, as illustrated in FIG. 4C, a blocking dielectric layer 7 is formed in the recesses 62 and in the front side opening 81. The blocking dielectric 7 does not completely fill the recess 62. Rather, the blocking dielectric 7 lines the walls of the recess 62, thereby forming a clam shaped portion of the blocking dielectric in the recess 62. In an embodiment, the blocking dielectric layer 7 is formed on an exposed edge surface 103 of the middle layer 3ₘ in each of the plurality of recesses 62, on exposed major surfaces 113A, 113B of the first and second control gate layers 3₁, 3₂ in each of the plurality of recesses 62 and on exposed edge surfaces 123 of the first and second control gate layers 3₁, 3₂ in the front side opening 81. Further, the edge surface 103 of the middle layer 3ₘ and the edge surfaces 123 of the first and second control gate layers 3₁, 3₂ extend substantially perpendicular to the major surface 100a of the substrate 100. Additionally, the major surfaces 113A, 113B of the first and second control gate layers 3₁, 3₂ extend substantially parallel to the major surface 100a of the substrate 100.

Next, a layer of charge storage material is deposited over the blocking dielectric layer 7 in the recesses 62 and on the surfaces of the front side openings 81 to form charge storage regions 9, as illustrated in FIG. 4D. In an embodiment, the remaining space 62A in the recesses 62 left after depositing the blocking dielectric layer 7 is filled with charge storage material, such as polysilicon, metal or dielectric. For example, a charge storage layer 9A may be deposited in space 62A in the recess 62 and in the front side opening 81 over the blocking dielectric over the edge surfaces 123 of the of the first and second control gate layers 3₁, 3₂. In an embodiment, the method also includes removing a portion of the charge storage layer 9A from the front side opening 81 to expose the blocking dielectric layer 7 located in the front side opening 81 on the edge surfaces 123 of the first and second control gate layers 3₁, 3₂, to leave a plurality of the charge storage regions 9 in a respective plurality of recesses 62 as illustrated in FIG. 4E. Preferably, the charge storage regions 9 are floating gates. In an embodiment, the plurality of charge storage regions 9 comprises a plurality of semiconducting or conducting floating gates.

Next, as illustrated in FIG. 4F, a tunnel dielectric 11 is deposited in the front side openings 81 over the blocking dielectric 7 and the exposed side surface 109 of the charge storage regions 9 in the front side openings 81. The channel 1 may then be formed by depositing semiconducting material in the front side openings 81, as illustrated in FIG. 4G. In an embodiment, the semiconducting channel 1 completely fills the remaining space in the front side opening similarly to the channel 1 illustrated in FIGS. 2A and 2B. Alternatively, the channel 1 may be pipe shaped and filled with an insulating material 2 similarly to the channel illustrated in FIGS. 1A and 1B. Next, the upper surface of the NAND string 180 may be planarized, such as by chemical mechanical polishing, to remove excess channel 1 material from the top surface of the stack 120, as illustrated in FIG. 4H. In the embodiment of FIGS. 4A-4M, the semiconductor channel 1 has a “U” shape with a horizontal portion 1c substantially parallel to the major surface 100a of the substrate 100 and two wing portions 1a, 1b substantially perpendicular to the major surface 100a of the substrate 100.

In an embodiment, the middle layer 3ₘ comprises an electrically conductive middle layer 3_{mc} which electrically contacts the first and second control gate layers 3₁, 3₂ in each control gate film 3. The electrically conductive middle layer 3_{mc} may comprise a metal or metal alloy, such as Ti, W, TiN, WN, WSi₂ or TiSi₂, etc. The first and second control gate layers 3₁, 3₂ may comprise any one or more suitable conductive or semiconductor control gate material known in the art, such as doped polysilicon, tungsten, copper, aluminum, tantalum, titanium, cobalt, titanium nitride or alloys thereof. For example, in some embodiments, polysilicon is preferred to allow easy processing.

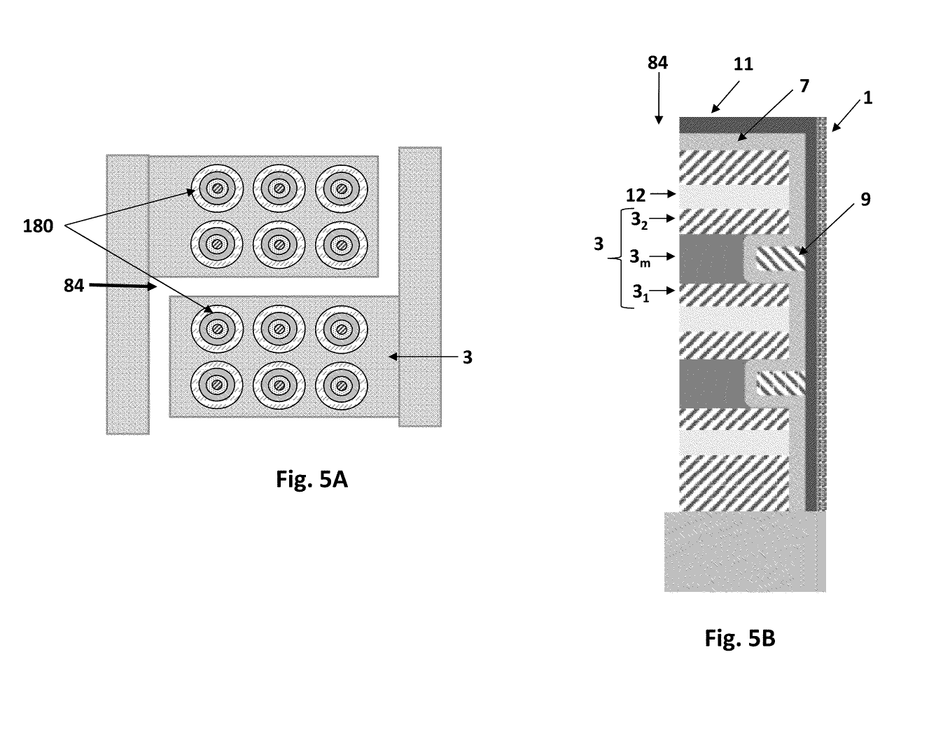

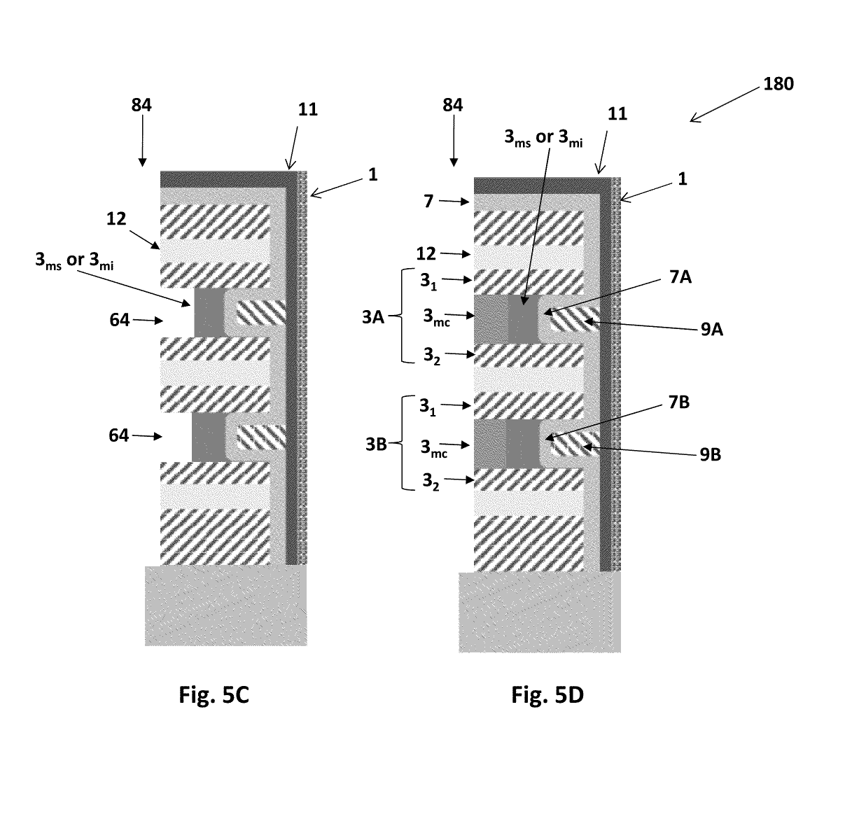

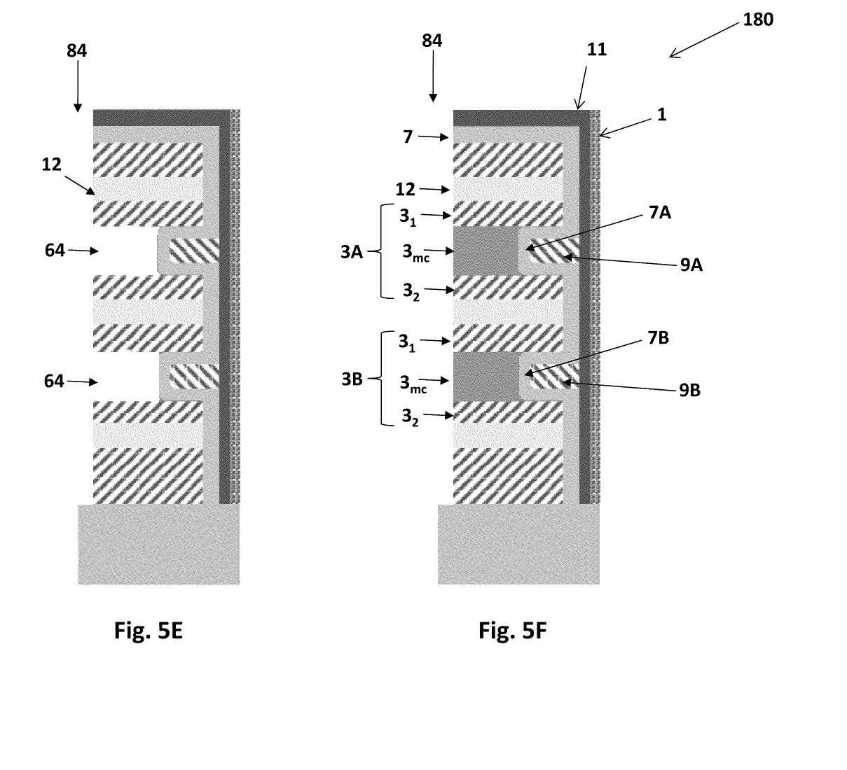

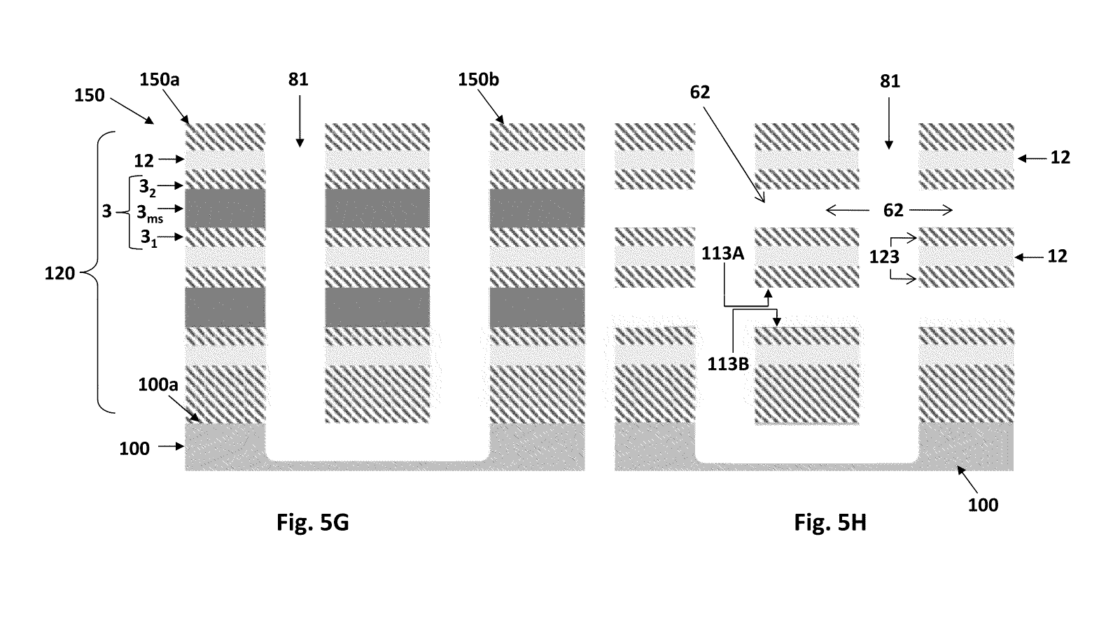

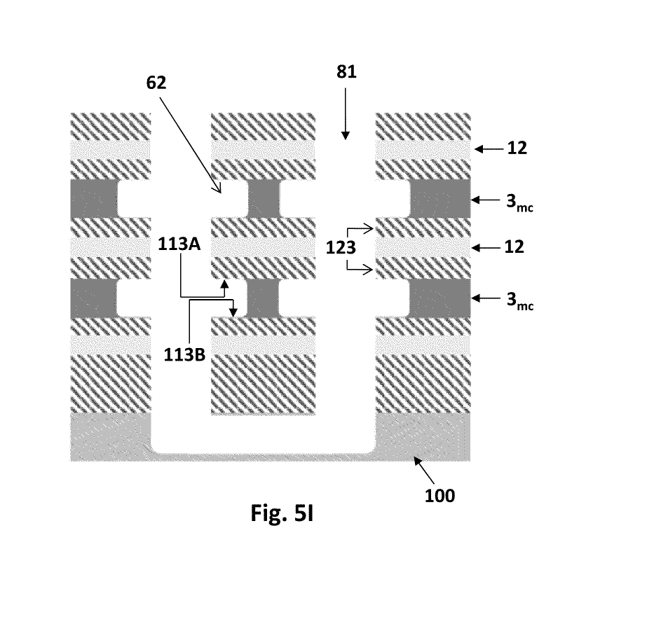

In an embodiment, the middle layer 3ₘ comprises a sacrificial middle layer 3ₘₛ as shown in FIGS. 5B-5D. In an embodiment, the sacrificial middle layer 3ₘₛ comprises silicon nitride and the insulating layers 12 comprise silicon oxide.

In one aspect of this alternative embodiment, the method further includes removing at least a portion of the sacrificial middle layer 3ₘₛ (and preferably the entire sacrificial middle layer 3ₘₛ) through the front side opening 81 in the stack 120 thereby forming a recess 62 between the first and second control gate layers 3₁, 3₂. The method also includes forming an electrically conductive middle layer 3_{mc} in the recess 62 through the front side opening 81 such that the electrically conducting middle layer 3_{mc} electrically contacts the first and second control gate layers 3₁, 3₂ in each control gate film 3. In an embodiment, the electrically conductive middle layer 3_{mc} comprises tungsten. However, any other metal or metal alloy (e.g. TiN, WN, TiSi₂, WSi₂, etc. may be used).

FIGS. 5A-5F illustrates alternative embodiments. In these embodiments, the methods include forming a back side opening 84 in the stack 120 (illustrated in FIGS. 5A, 5B) such as a slit trench between adjacent word lines/control gates 3.

In one alternative embodiment, the middle layer 3ₘ comprises a permanent (i.e. not sacrificial) insulating middle material 3ₘᵢ. In this embodiment, the method further includes forming a back side opening 84 in the stack 120, removing a portion of the insulating middle layer 3ₘᵢ through the back side opening 84 in the stack 120 thereby forming a back side recess 84 between the first and second control gate layers 3₁, 3₂, as shown in FIG. 5C. The method also includes forming an electrically conductive connection layer 3_{mc} in the back side recess 64 through the back side opening 84 such that the electrically conducting connection layer 3_{mc} electrically contacts the first and second control gate layers 3₁, 3₂ in each control gate film 3. The electrically conductive connection layer 3_{mc} is separated from the front side opening 81 by a remaining portion of the insulating middle layer 3ₘᵢ, as shown in FIG. 5D. In an embodiment, the insulating middle layer 3ₘᵢ comprises silicon nitride and the insulating layers 12 comprise silicon oxide.

In another alternative embodiment, the method includes a sacrificial middle layer. The method include removing at least a portion (e.g. preferably all or at least a part) of the sacrificial middle layer 3ₘₛ through the back side opening 84 in the stack 120 (illustrated in FIG. 5E), thereby forming a back side recess 84 between the first and second control gate layers 3₁, 3₂. The method also includes forming an electrically conductive middle layer 3_{mc} in the recess 64 through the back side opening 84 such that the electrically conducting middle layer electrically contacts the first and second control gate layers 3₁, 3₂ in each control gate film 3, as illustrated in FIG. 5F. In an embodiment, the electrically conductive middle layer 3_{mc} comprises tungsten. In the alternative embodiment method illustrated in FIGS. 5E and 5F, the entire sacrificial middle layer 3ₘₛ, is removed and replaced with an electrically conductive middle layer 3_{mc}. However, any other metal or metal alloy (e.g. TiN, WN, TiSi₂, WSi₂, etc. may be used).

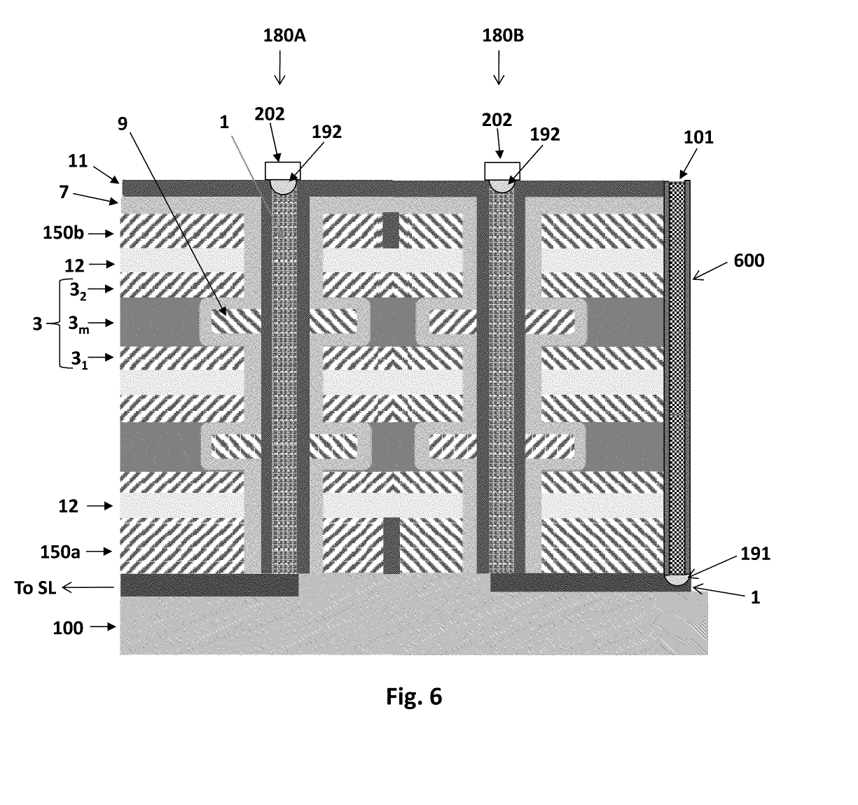

In another embodiment, the semiconductor channel 1 has a pillar shape and at least a majority of the entire semiconductor channel 1 extends substantially perpendicular to the major surface 100a of the substrate 100 in each string 180A, 180B as shown in FIG. 6. Embodiments with conductive, sacrificial and insulating middle layers 3_{mc}, 3ₘₛ, 3ₘᵢ, shown in FIGS. 5A-5F may have either the pillar shape of FIG. 5 or U-shape of FIG. 4H.

Embodiments are also drawn to monolithic three dimensional NAND string 180. One embodiment is drawn to a monolithic three dimensional NAND string 180 having a stack 120 of alternating insulating layers 12 and control gate films 3 over a major surface 100a of a substrate 100. Each of the control gate films 3 includes an insulating middle layer 3ₘₛ located between a first control gate layer 3₁ and a second control gate layer 3₂, the insulating middle layer 3ₘₛ is made of a different material from the first and second control gate layers 3₁, 3₂ and from the insulating layers 12, as shown in FIG. 5D for example. The NAND string 180 also includes a semiconductor channel 1 in which at least one end of the semiconductor channel 1 extends through the stack 120 substantially perpendicular to the major surface 100a of the substrate 100. The NAND string 180 also includes a first charge storage region 9 and a first portion 7A of a blocking dielectric 7 located in a recess 62 between the first and the second control gate layers 3₁, 3₂ of a first control gate film 3A in a first device level as shown in FIG. 5D. The first portion 7A of the blocking dielectric 7 is located between the first charge storage region 9 and the insulating middle layer 3ₘₛ of the first control gate film 3A. The NAND string 180 also includes a first electrically conductive connection layer 3_{mc} which contacts the first and second control gate layers 3₁, 3₂ in the first control gate film 3A such that the first electrically conductive connection layer 3_{mc} is separated from the first charge storage region 9 by the insulating middle layer 3ₘₛ of the first control gate film 3A. The NAND string 180 also includes a second charge storage region 9B and a second portion 7B of the blocking dielectric 7 located in a recess 62 between the first and the second control gate layers 3₁, 3₂ of a second control gate film 3B in a second device level located below the first device level. The second portion 7B of the blocking dielectric 7 is located between the second charge storage region 9B and the insulating middle layer 3ₘₛ of the second control gate film 3B. A second electrically conductive connection layer 3_{mc} which contacts the first and second control gate layers 3₁, 3₂ in the second control gate film 3B such that the second electrically conductive connection layer 3_{mc} is separated from the second charge storage region 9B by the insulating middle layer 3ₘₛ of the second control gate film 3B. The NAND string 180 also includes a tunnel dielectric 11 located between the semiconductor channel 1 and the first and second charge storage regions 9A, 9B.

In an embodiment, the tunnel dielectric 11 has a straight sidewall, the first 7A and the second 7B portions of the blocking dielectric 7 each have a clam shape and the first and the second charge storage regions 9A, 9B comprise respective first and second floating gates which are located in an opening 62 in respective clam shaped first and second portions of the blocking dielectric 7.

In one embodiment shown in FIG. 6, the semiconductor channel 1 has a pillar shape, the entire semiconductor channel 1 extends substantially perpendicular to the major surface 100a of the substrate 100, a first select gate 150a is located adjacent to a first end (e.g. lower source 191) of the semiconductor channel 1, a second select gate 150b is located adjacent to a second end (e.g. upper drain 192) of the semiconductor channel 1, a first electrode 102 (e.g. a source line located in a trench adjacent the control gates 3 and insulated from the control gates 3 with an insulating layer 600 lining the trench) which electrically contacts the first end (e.g. the source 191) of the semiconductor channel 1 and a second electrode 202 which contacts the second end (e.g. drain 192) of the semiconductor channel 1.

In another embodiment, the semiconductor channel has a “U” shape with a horizontal portion 1c substantially parallel to the major surface 100a of the substrate 100 and first and second wing portions 1a, 1b substantially perpendicular to the major surface 100a of the substrate 100b as shown in FIG. 4H. The NAND string 180 of this embodiment also has a first select gate 150a that is located adjacent to the first wing portion 1a, a second select gate 150b that is located adjacent to the second wing portion 1b, a first electrode 202₁ which contacts the first wing portion 1a and a second electrode 202₂ which contacts the second wing portion 1b.

Although the foregoing refers to particular preferred embodiments, it will be understood that the invention is not so limited. It will occur to those of ordinary skill in the art that various modifications may be made to the disclosed embodiments and that such modifications are intended to be within the scope of the invention. All of the publications, patent applications and patents cited herein are incorporated herein by reference in their entirety.

What is claimed is:

1. A method of making a monolithic three dimensional NAND string, comprising:
providing a stack of alternating insulating layers and control gate films over a major surface of a substrate, each of the control gate films comprising: a middle layer located between a first control gate layer and a second control gate layer, the middle layer comprising a different material from the first and second control gate layers and from the insulating layers;
forming a front side opening in the stack; and
forming a blocking dielectric, at least one charge storage region, a tunnel dielectric and a semiconductor channel in the front side opening in the stack.

2. The method of claim 1, further comprising removing a portion of the middle layer through the front side opening in the stack thereby forming a plurality of recesses, wherein each of the plurality of recesses is located in each respective control gate film between the first and second control gate layers.

3. The method of claim 2, wherein forming the blocking dielectric comprises forming the blocking dielectric layer in the recesses and in the front side opening.

4. The method of claim 3, wherein:
the blocking dielectric is formed on an exposed edge surface of the middle layer in each of the plurality of recesses, on exposed major surfaces of the first and second control gate layers in each of the plurality of recesses, and on exposed edge surfaces of the first and second control gate layers in the front side opening;
the edge surface of the middle layer and the edge surfaces of the first and second control gate layers extend substantially perpendicular to the major surface of the substrate; and
the major surfaces of the first and second control gate layers extend substantially parallel to the major surface of the substrate.

5. The method of claim 4, wherein forming the at least one charge storage region comprises:
depositing a charge storage layer over the blocking dielectric;
removing a portion of the charge storage layer from the front side opening to expose the blocking dielectric located in the front side opening on the edge surfaces of the first and second control gate layers, to leave a plurality of the charge storage regions in a respective plurality of recesses.

6. The method of claim 5, wherein:
the plurality of charge storage regions comprise a plurality of floating gates;
forming the tunnel dielectric comprises depositing the tunnel dielectric on the blocking dielectric and on exposed portions of the plurality of charge storage regions in the front side opening; and
forming the semiconductor channel comprises depositing the semiconductor channel on the tunnel dielectric in the front side opening.

7. The method of claim 1, wherein the middle layer comprises an electrically conductive middle layer which electrically contacts the first and second control gate layers in each control gate film.

8. The method of claim 1, wherein the middle layer comprises a sacrificial middle layer.

9. The method of claim 8, wherein the sacrificial middle layer comprises silicon nitride and the insulating layers comprise silicon oxide.

10. The method of claim 8, further comprising:
removing at least a portion of the sacrificial middle layer through the front side opening in the stack thereby forming a recess between the first and second control gate layers; and
forming an electrically conductive middle layer in the recess through the front side opening such that the electrically conducting middle layer electrically contacts the first and second control gate layers in each control gate film.

11. The method of claim 10, wherein the electrically conductive middle layer comprises tungsten.

12. The method of claim 8, further comprising:
forming a back side opening in the stack;
removing at least a portion of the sacrificial middle layer through the back side opening in the stack thereby forming a recess between the first and second control gate layers; and
forming an electrically conductive middle layer in the recess through the back side opening such that the electrically conducting middle layer electrically contacts the first and second control gate layers in each control gate film.

13. The method of claim 12, wherein the electrically conductive layer comprises tungsten.

14. The method of claim 1, wherein the middle layer comprises an insulating middle layer, and further comprising:
forming a back side opening in the stack;
removing a portion of the insulating middle layer through the back side opening in the stack thereby forming a recess between the first and second control gate layers; and
forming an electrically conductive connection layer in the recess through the back side opening such that the electrically conducting connection layer electrically contacts the first and second control gate layers in each control gate film and such that the electrically conductive connection layer is separated from the front side opening by a remaining portion of the insulating middle layer.

15. The method of claim 14, wherein the insulating middle layer comprises silicon nitride and the insulating layers comprise silicon oxide.

16. The method of claim 1, wherein:
the semiconductor channel has a pillar shape; and
the entire semiconductor channel extends substantially perpendicular to the major surface of the substrate.

17. The method of claim 1, wherein the semiconductor channel has a “U” shape with a horizontal portion substantially parallel to the major surface of the substrate and two wing portions substantially perpendicular to the major surface of the substrate.

18. A monolithic three dimensional NAND string, comprising:
a stack of alternating insulating layers and control gate films over a major surface of a substrate, each of the control gate films comprising: an insulating middle layer located between a first control gate layer and a second control gate layer, the insulating middle layer comprising a different material from the first and second control gate layers and from the insulating layers;
a semiconductor channel, wherein at least one end of the semiconductor channel extends through the stack substantially perpendicular to the major surface of the substrate;
a first charge storage region and a first portion of a blocking dielectric located in a recess between the first and the second control gate layers of a first control gate film in a first device level, wherein the first portion of the blocking dielectric is located between the first charge storage region and the insulating middle layer of the first control gate film;
a first electrically conductive connection layer which contacts the first and second control gate layers in the first control gate film, wherein the first electrically conductive connection layer is separated from the first charge storage region by the insulating middle layer of the first control gate film;
a second charge storage region and a second portion of the blocking dielectric located in a recess between the first and the second control gate layers of a second control gate film in a second device level, wherein the second portion of the blocking dielectric is located between the second charge storage region and the insulating middle layer of the second control gate film;
a second electrically conductive connection layer which contacts the first and second control gate layers in the second control gate film, wherein the second electrically conductive connection layer is separated from the second charge storage region by the insulating middle layer of the second control gate film; and
a tunnel dielectric located between the semiconductor channel and the first and second charge storage regions.

19. The monolithic three dimensional NAND string of claim 18, wherein:
the tunnel dielectric has a straight sidewall;
the first and the second portions of the blocking dielectric each have a clam shape; and
the first and the second charge storage regions comprise respective first and second floating gates which are located in an opening in respective clam shaped first and second portions of the blocking dielectric.

20. The monolithic three dimensional NAND string of claim 18, wherein:
the semiconductor channel has a pillar shape;
the entire semiconductor channel extends substantially perpendicular to the major surface of the substrate;
a first select gate is located adjacent to a first end of the semiconductor channel;
a second select gate is located adjacent to a second end of the semiconductor channel;
a first electrode which contacts the first end of the semiconductor channel; and
a second electrode which contacts the second end of the semiconductor channel.

21. The monolithic three dimensional NAND string of claim 18, wherein:
the semiconductor channel has a “U” shape with a horizontal portion substantially parallel to the major surface of the substrate and first and second wing portions substantially perpendicular to the major surface of the substrate;
a first select gate is located adjacent to the first wing portion;
a second select gate is located adjacent to the second wing portion;
a first electrode which contacts the first wing portion; and
a second electrode which contacts the second wing portion.

22. The monolithic three dimensional NAND string of claim 18, wherein the insulating middle layer comprises silicon nitride and the insulating layers comprise silicon oxide.
